(19) United States
(12) Patent Application Publication
(10) Pub. No.: US 2012/0282733 A1
(43) Pub. Date: Nov. 8, 2012

(54) METHOD FOR BAND GAP TUNING OF METAL OXIDE SEMICONDUCTORS

(76) Inventors: Szetsen Steven LEE, Taipei City (TW); Jr-Wei Peng, Hsinchu County (TW)

(21) Appl. No.: 13/207,820

(22) Filed: Aug. 11, 2011

(30) Foreign Application Priority Data
May 3, 2011 (TW) 100115434

(51) Int. Cl. H01L 21/428

(52) U.S. Cl. 438/104; 438/771; 257/E21.475

(57) ABSTRACT

A method for band gap tuning of metal oxide semiconductors is provided, comprising: placing a metal oxide semiconductor in a plasma chamber; (a1) treating the metal oxide semiconductor with an oxygen plasma for oxidizing the metal oxide semiconductor to decrease band gap thereof; and (a2) treating the metal oxide semiconductor with a hydrogen plasma for reducing the metal oxide semiconductor to increase band gap thereof; or (b1) treating the metal oxide semiconductor with an oxygen plasma for oxidizing the metal oxide semiconductor to increase band gap thereof; and (b2) treating the metal oxide semiconductor with a hydrogen plasma for reducing the metal oxide semiconductor to decrease band gap thereof.

### CROSS REFERENCE TO RELATED APPLICATIONS

This Application claims priority of Taiwan Patent Application No.100115434, filed on May 3, 2011, the entirety of which is incorporated by reference herein.

### BACKGROUND OF THE INVENTION

1. Field of the Invention

The invention relates to a method for band gap tuning of metal oxide semiconductors, and in particular relates to a plasma treatment method for band gap tuning of the metal oxide semiconductors.

2. Description of the Related Art

Metal oxide semiconductors including zinc oxide (ZnO), copper oxide (CuO), and tin dioxide (SnO₂), for example, can be used as optoelectronic semiconductor materials, and they are used in various applications such as light-emitting diodes, photovoltaic cells, piezoelectric transducers, optical waveguides, surface acoustic wave devices, and varistors. By tuning the band gap of the metal oxide semiconductors, desired emission colors and wavelengths that are suitable for specific applications can be obtained.

Currently, the most common method for band gap tuning of metal oxide semiconductors is by adding dopants such as aluminum, sulfur, chloride, nitrogen, indium, hydrogen, oxygen, and other transition metals. For zinc oxide, it has a band gap energy of about 3.37 eV. When doping zinc oxide thin films with Al (Al-doped ZnO), the resultant band gap energy is about 3.29 eV. Meanwhile, when sulfur is used as the dopant, a spectral line shift of near-band-edge emission in the photoluminescence spectrum of zinc oxide is observed, proving that the band gap energy of zinc oxide is changed due to the addition of the sulfur. If electrodeposition is employed to produce zinc oxide, the concentration of chloride would influence the band gap energy of the zinc oxide. Although the band gap of metal oxide semiconductors can be tuned by adding dopants, this method has the following disadvantages: (1) since dopants are usually added during the growth of metal oxide semiconductors, if the distribution of dopants is non-uniform, it is difficult to make adjustments to obtain a desired band gap energy; (2) if the metal oxide semiconductors have nanostructures, it is necessary to ensure that overgrowth or phase separation of dopants do not occur when adding the dopants; (3) dopants that are not fully reacted become impurities in the metal oxide semiconductors; (4) use of dopants may result in environmental pollution.

So far, much research relating to treating metal oxide semiconductors with plasma has been carried out. For example, zinc oxide thin films have been treated with hydrogen plasma to observe the effect of defect formation on electrical and optical properties. Also, zinc oxide nanowires have been treated with argon plasma to change conductivities of the nanowires and zinc oxide nanotubes have been exposed under nitrogen plasma to observe changes in photoresponses. For treating zinc oxide with oxygen plasma, research interests have mostly been in observing the effect of defect formation on electrical and optical properties. Although it is known in the prior art that plasma treatments can be carried out to change the surface structure of zinc oxide to change the electrical and optical properties thereof, however, there has not yet been any research on combining respective oxygen plasma treatments and hydrogen plasma treatments for reversible band gap energy tuning.

### BRIEF SUMMARY OF THE INVENTION

A method for band gap tuning of metal oxide semiconductors is provided, comprising: placing a metal oxide semiconductor in a plasma chamber; (a1) treating the metal oxide semiconductor with an oxygen plasma for oxidizing the metal oxide semiconductor to decrease band gap thereof; and (a2) treating the metal oxide semiconductor with a hydrogen plasma for reducing the metal oxide semiconductor to increase band gap thereof; or (b1) treating the metal oxide semiconductor with an oxygen plasma for oxidizing the metal oxide semiconductor to increase band gap thereof; and (b2) treating the metal oxide semiconductor with a hydrogen plasma for reducing the metal oxide semiconductor to decrease band gap thereof.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a setup for plasma treatment of metal oxide semiconductors according to embodiments of the invention;

FIG. 2 is a plot of the change in band gap energy of a zinc oxide thin film after the zinc oxide thin film has been treated with oxygen plasma first and then with hydrogen plasma, according to an embodiment of the invention;

FIG. 3 is a plot of the change in band gap energy of a zinc oxide thin film after the zinc oxide thin film has been treated with hydrogen plasma first and then with oxygen plasma, according to an embodiment of the invention;

FIG. 4 is a plot of the change in band gap energy of tin dioxide after tin dioxide has been treated with hydrogen plasma first and then with oxygen plasma, according to an embodiment of the invention; and

FIG. 5 is a plot of the change in band gap energy of copper oxide nanowires after the copper oxide nanowires have been treated with hydrogen plasma first and then with oxygen plasma, according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

This invention is mainly directed to using oxygen plasma (for oxidization) and hydrogen plasma (for reduction) for reversible band gap tuning of metal oxide semiconductors. Compared with chemical doping methods, the method of this invention is more precise, more convenient, faster, and more environmentally-friendly. Moreover, this method is repeatable and reversible.

Metal oxide semiconductors suitable for this invention include various optoelectronic materials that can be used in applications such as light-emitting diodes, photovoltaic cells, piezoelectric transducers, optical waveguides, surface acoustic wave devices, and varistors. Moreover, the metal oxide semiconductors may include zinc oxide, tin dioxide, copper oxide, or any combinations of the above for example. The aforementioned metal oxide semiconductors may be synthesized by methods such as hydrothermal synthesis, template synthesis, chemical vapor deposition, or sputtering. For example, hydrothermal synthesis may be employed for synthesizing zinc oxide thin films with source materials Zn(NO₃)₂.6H₂O or Zn(CH₃COO)₂.6H₂O, hexamethylenetetramine (HMTA), and de-ionized water. Alternatively, SnO₂ may be synthesized at room temperature using a cationic surfactant cetyltrimethylammonium bromide (CTAB) as the organic supramolecular template, and hydrous tin chloride (SnCl₄.5H₂O) and NH₄OH as the inorganic precursor. (Wang, Y.; Ma, C.; Sun, X.; Li, H. Mater. Lett. 2001, 51, 285-288). Alternatively, CuO and Cu₂O nanowires may be synthesized using Cu(OH)₂ nanowire templates (Wang, W.; Varghese, O. K.; Ruan, C.; Paulose, M.; Grimes, C. A. J. Mater. Res. 2003, 18(12), 2756-2759). In this invention, the structures of the metal oxide semiconductors are not particularly limited and may include thin films, nanorods, nanowires, nanocrystals, mesostructures, or any combinations of the above. For the same metal oxide semiconductor, the initial value of band gap energy may be influenced by the method of synthesis and/or size. For example, uniformity issues or impurities may be inevitable during synthesis, affecting the initial value of the band gap energy of the metal oxide semiconductor. Therefore, by using the band gap tuning method of the invention, fine-tuning of band gap energy of metal oxide semiconductors can be achieved, optimizing the performance of components (for example, light-emitting components).

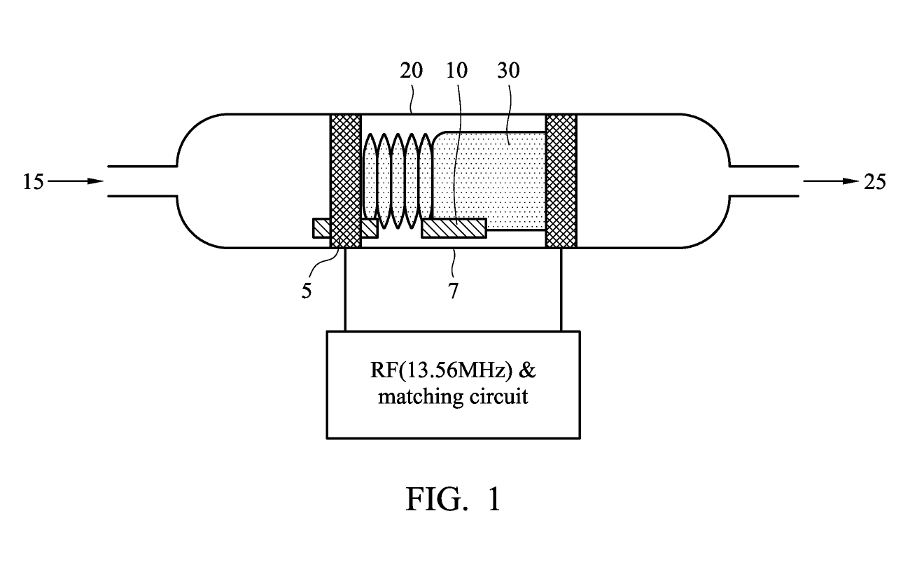

In the first embodiment of the invention, an oxygen plasma treatment is carried out first, and a hydrogen plasma treatment is carried out subsequently. First, a metal oxide semiconductor 10 is disposed in a plasma chamber 20 for carrying out the oxygen plasma treatment process, as shown in FIG. 1. The metal oxide semiconductor 10 can be disposed anywhere in the plasma chamber 20, for example, the metal oxide semiconductor 10 can be disposed at the cathode 5 or at the positive column 7. In an embodiment, the metal oxide semiconductor 10 is a zinc oxide thin film with a thickness of about 200-300 nm A.C. or pulsed D.C. power supplies can be used to generate a plasma 30, and various methods for applying the plasma including capacitively coupled plasma (CCP), inductively coupled plasma (ICP), magnetron sputtering plasma, electron cyclotron resonance (ECR), ion cyclotron resonance (ICR), microwave, and radio frequency (RF) may be used. In a preferred embodiment, an A.C. radio frequency capacitively coupled plasma is used. In this embodiment, the frequency may be 13.56 MHz, and the power output may be about 20-50 W. However, the power output can be adjusted to be higher or lower depending on different needs. Oxygen gas is pumped into the plasma chamber 20 (an arrow 15 represents the direction in which the gas is pumped into the plasma chamber 20), thus forming an oxygen plasma. The flow rate of the oxygen gas may be about 5-10 sccm, the operational pressure may be about 100-200 mtorr, and the duration of the oxygen plasma treatment may be about 5-20 minutes. The direction in which the oxygen gas is pumped out is represented by an arrow 25. The oxygen plasma can oxidize the metal oxide semiconductor 10, and the chemical reaction that occurs during oxidation is shown in equation (1) below, wherein M represents a semiconductor metal including zinc, tin, or copper, and MO:M represents the metal-rich metal oxide semiconductor 10:

MO:M+1/2O₂→MO (1)

After the oxygen plasma treatment process, the band gap energy of metal oxide semiconductor 10 may be increased or decreased.

Then, a hydrogen plasma treatment is carried out, which is similar to the oxygen plasma treatment described previously: hydrogen gas is pumped into the plasma chamber 20 in the direction of the arrow 15, thus forming a hydrogen plasma. The flow rate of hydrogen gas may be about 5-10 sccm, the operational pressure may be 100-200 mtorr, and the duration of the hydrogen plasma treatment may be 5-20 minutes. The hydrogen gas is pumped out in the direction of the arrow 25. Hydrogen plasma can reduce the metal oxide semiconductor 10, and the chemical reaction that occurs during the reduction is shown below in equation (2):

MO+H₂→H₂O+M (2)

After the hydrogen plasma treatment process, if the band gap energy of the metal oxide semiconductor 10 was increased previously after the oxygen plasma treatment process, then the band gap energy of the metal oxide semiconductor 10 would decrease, but if the band gap energy of the metal oxide semiconductor 10 was decreased previously after the oxygen plasma treatment process, then the band gap energy of the metal oxide semiconductor 10 would increase.

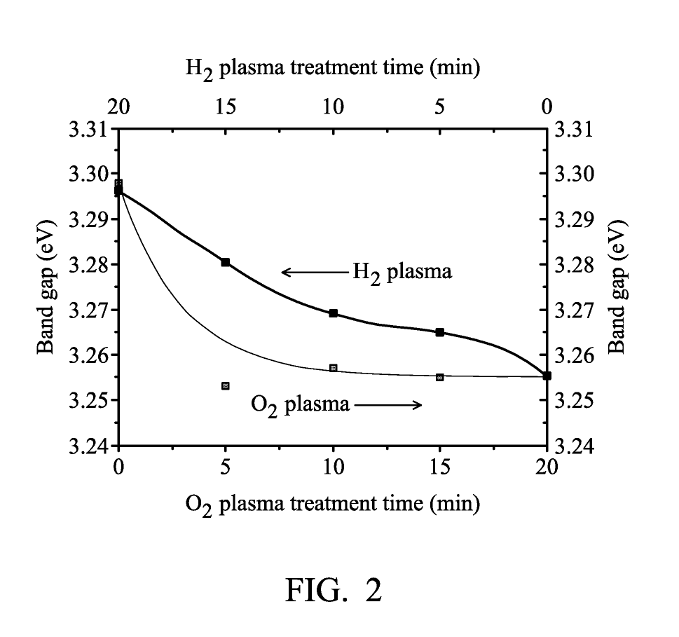

Referring to FIG. 2, it shows a plot of the change in band gap energy of a zinc oxide thin film after the zinc oxide thin film has been treated with oxygen plasma first and then with hydrogen plasma, according to an embodiment of the invention. Band gap energies are measured by combining the use of a UV-Vis spectrometer and an integrating sphere to collect diffuse reflectance spectra. Absorption coefficients and photon energies are used to form Tauc plots, and the band gap energy of a given sample is the energy of the abscissa intercept found by extrapolating the tangent line of the band edge in the Tauc plot. Detailed descriptions of measurements and calculations of band gap energies can be found in Tan, S. T.; Chen, B. J.; Sun, X. W.; Fan, W. J.; Kwok, H. S.; Zhang, X. H.; Chua, S. J. J. Appl. Phys. 2005, 98, 013505. In the embodiment shown in FIG. 2, the thickness of the zinc oxide thin film was about 200-300 nm, the power output of the radio frequency plasma generator was about 50 W, the respective durations of the oxygen plasma treatment and the hydrogen plasma treatment were about 20 minutes, the respective flow rates of oxygen gas and hydrogen gas were about 10 sccm, and the respective operational pressures of the oxygen plasma and the hydrogen plasma were about 200 mtorr. FIG. 2 shows that the band gap energy of the untreated zinc oxide thin film was about 3.29-3.30 eV, and after the oxygen plasma treatment process, band gap energy decreased to 3.25-3.26 eV. Then, the hydrogen plasma treatment was carried out, and after the treatment, the band gap energy increased to about 3.29-3.30 eV. Therefore, the range for tuning was about 0.04-0.05 eV.

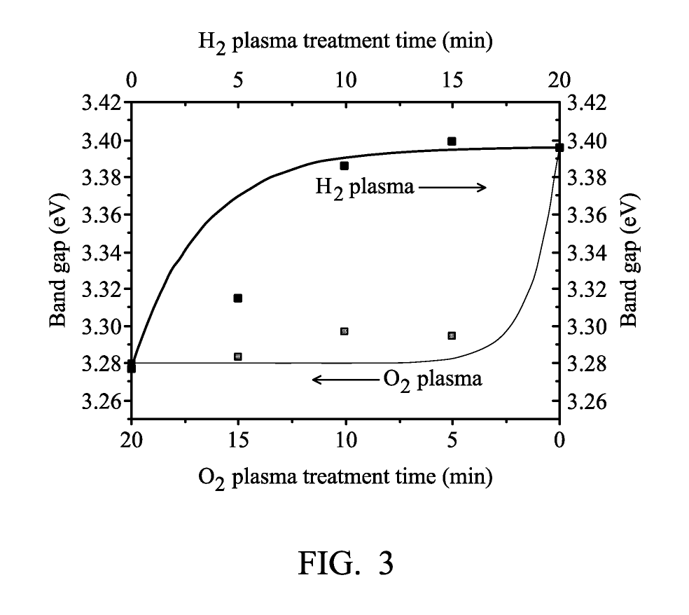

The second embodiment of the invention is similar to the first embodiment except that in the second embodiment, the hydrogen plasma treatment is carried out first, and the oxygen plasma treatment is carried out subsequently. First, a metal oxide semiconductor 10 is disposed in a plasma chamber 20 for carrying out a hydrogen plasma treatment process, as shown in FIG. 1. Similarly, the metal oxide semiconductor 10 may be disposed anywhere in the plasma chamber 20, for example, the metal oxide semiconductor 10 can be disposed at the cathode 5 or at the positive column 7. In an embodiment, the metal oxide semiconductor is a zinc oxide thin film with a thickness of about 200-300 nm. A.C. or pulsed D.C. power sources may be used to generate a plasma 30, and various methods for applying the plasma including capacitively coupled plasma (CCP), inductively coupled plasma (ICP), magnetron sputtering plasma, electron cyclotron resonance (ECR), ion cyclotron resonance (ICR), microwave, and radio frequency (RF) may be used. In a preferred embodiment, an A.C. radio frequency capacitively coupled plasma is used. In this embodiment, the frequency may be 13.56 MHz, and the power output may be about 20-50 W. However, the power output may be adjusted to be higher or lower depending on different needs. Hydrogen gas is pumped into the plasma chamber 20 (an arrow 15 represents the direction in which the gas is pumped into the plasma chamber 20), thus forming a hydrogen plasma. The flow rate of the hydrogen gas may be about 5-10 sccm, the operational pressure may be about 100-200 mtorr, and the duration of the hydrogen plasma treatment may be about 5-20 minutes. The direction in which the hydrogen gas is pumped out is represented by an arrow 25. The hydrogen plasma can reduce the metal oxide semiconductor 10, and the chemical reaction that occurs during the reduction is the same as (2) described previously. After the hydrogen plasma treatment process, the band gap energy of metal oxide semiconductor 10 may be increased or decreased. Then, an oxygen plasma treatment is carried out, which is similar to the oxygen plasma treatment described previously: oxygen gas is pumped into the plasma chamber 20 in the direction of the arrow 15, thus forming an oxygen plasma. The flow rate of oxygen gas may be about 5-10 sccm, the operational pressure may be 100-200 mtorr, and the duration of the oxygen plasma treatment may be 5-20 minutes. The oxygen gas is pumped out in the direction of the arrow 25. Oxygen plasma can oxidize the metal oxide semiconductor 10, and the chemical reaction that occurs during the oxidation is the same as equation (1) described previously. After the oxygen plasma treatment process, if the band gap energy of the metal oxide semiconductor 10 was increased previously after the hydrogen plasma treatment process, then the band gap energy of the metal oxide semiconductor 10 would decrease, but if the band gap energy of the metal oxide semiconductor 10 was decreased previously after the hydrogen plasma treatment process, then the band gap energy of the metal oxide semiconductor 10 would increase. Referring to FIG. 3, it shows a plot of the change in band gap energy of a zinc oxide thin film after the zinc oxide thin film has been treated with hydrogen plasma first and then with oxygen plasma, according to an embodiment of the invention. In this embodiment, the thickness of the zinc oxide thin film was about 200-300 nm, the power output of the radio frequency plasma generator was about 50 W, the respective durations of the oxygen plasma treatment and the hydrogen plasma treatment were about 20 minutes, the respective flow rates of the oxygen gas and the hydrogen gas were about 10 sccm, and the respective operational pressures of the oxygen plasma and the hydrogen plasma were about 200 mtorr. FIG. 3 shows that the band gap energy of the untreated zinc oxide thin film was about 3.27-3.28 eV, and after the hydrogen plasma treatment process, band gap energy increased to 3.39-3.40 eV. Then, the oxygen plasma treatment was carried out, and after the treatment, the band gap energy decreased back to about 3.27-3.28 eV. Therefore, the range for tuning was about 0.10-0.12 eV.

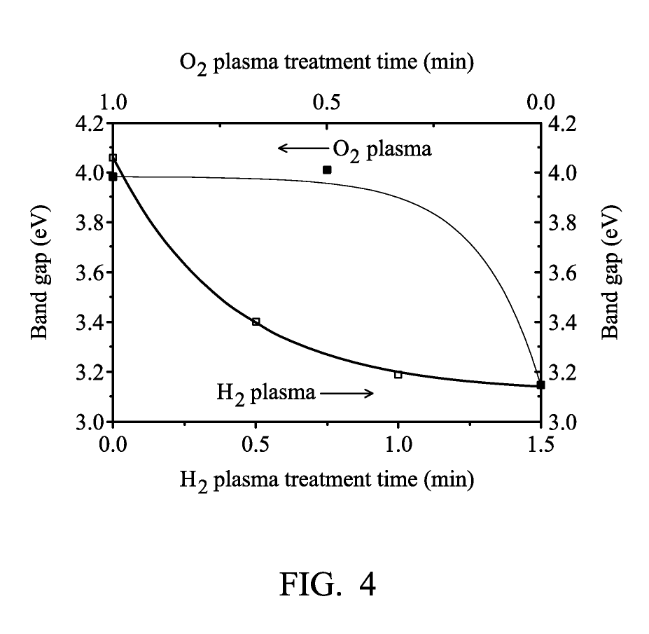

Referring to FIG. 4, it shows a plot of the change in band gap energy of tin dioxide (SnO₂) after tin dioxide has been treated with hydrogen plasma first and then with oxygen plasma, according to an embodiment of the invention. In this embodiment, the power output of the radio frequency plasma generator is about 50 W, the respective durations of the oxygen plasma treatment and the hydrogen plasma treatment are about 20 minutes, the respective flow rates of the oxygen gas and the hydrogen gas are about 10 sccm, and the respective operational pressures of oxygen plasma and hydrogen plasma are about 200 mtorr. FIG. 4 shows that the band gap energy of the untreated tin dioxide was about 4.0-4.1 eV, and after the hydrogen plasma treatment process, band gap energy decreased to 3.1-3.2 eV. Then, the hydrogen plasma treatment was carried out, and after the treatment, the band gap energy increased to about 3.9-4.0 eV. Therefore, the range for tuning was about 0.7-1.0 eV.

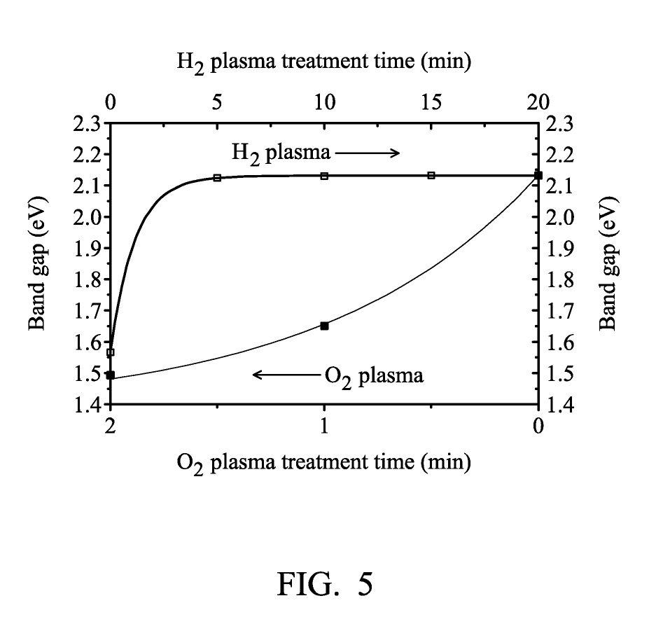

Referring to FIG. 5, it shows a plot of the change in band gap energy of copper oxide (CuO) nanowires after the copper oxide nanowires have been treated with hydrogen plasma first and then with oxygen plasma, according to an embodiment of the invention. In this embodiment, the power output of the radio frequency plasma generator is about 50 W, the respective durations of the oxygen plasma treatment and the hydrogen plasma treatment are about 20 minutes, the respective flow rates of the oxygen gas and the hydrogen gas are about 10 sccm, and the respective operational pressures of oxygen plasma and hydrogen plasma are about 200 mtorr. FIG. 5 shows that the band gap energy of the untreated copper oxide was about 1.5-1.6 eV, and after the hydrogen plasma treatment process, band gap energy increased to 2.1-2.2 eV. Then, the oxygen plasma treatment was carried out, and after the treatment, the band gap energy decreased to about 1.4-1.5 eV. Therefore, the range for tuning was about 0.5-0.8 eV.

When SnO₂ and CuO are respectively treated with hydrogen plasma, the lower oxidation state Sn²⁺ and Sn⁰ form in SnO₂, and the lower oxidation state Cu⁺ and Cu⁰ form in CuO. The formation of these lower oxidation species cause structural changes that result in significant changes in band gap energies. As shown in FIG. 4, after treating the SnO₂ (band gap energy about 4.1 eV) with hydrogen plasma, the SnO₂ can almost completely turn into SnO (band gap energy about 3.1 eV). Similarly, as shown in FIG. 5, after treating the CuO (band gap energy about 1.5 eV) with hydrogen plasma, the CuO can almost completely turn into Cu₂O (band gap energy about 2.1 eV). Therefore, opposite trends for changes in band gap energies are observed for ZnO and CuO.

The common feature of SnO₂ and CuO is that if they were treated with oxygen plasma first, then their band gap energies would almost remain unchanged. However, if SnO₂ and CuO were treated with hydrogen plasma first, then the changes in band gap energies would become significant, as described previously. A possible explanation is as follows: tin ions and copper ions each have two stable oxidation states, which are Sn²⁺ and Sn⁴⁺, and Cu⁺ and Cu²⁺, respectively, so that their structures are different. However, there is only one stable oxidation state, Zn²⁺, for zinc ions. Therefore, when ZnO is treated with oxygen plasma, the remaining Zn atoms can be oxidized to the Zn²⁺ oxidation state, increasing the crystallinity of ZnO. On the other hand, when CuO is treated with oxygen plasma, the few remaining copper atoms are be first oxidized to the Cu⁺ oxidation state and then to the Cu²⁺ oxidation state. Since there is a discrepancy between the band gap energy values of CuO (about 1.2 eV) and Cu₂O (about 2.1 eV), even if Cu₂O is produced, it does not affect the band gap energy of CuO significantly. When SnO₂ is treated with oxygen plasma, the few remaining tin atoms are oxidized into Sn²⁺ and then Sn⁴⁺. However, since there is also a discrepancy between the band gap energies of SnO2 (about 3.62 eV) and SnO (about 2.5-3 eV), and SnO is not produced in large amounts, oxygen plasma does not affect the band gap energy significantly.

In the two embodiments described above, desired band gap energies may be obtained by varying different parameters such as the type of plasma generator used and its amount of power output, the kind of gas used, and the order in which the gases are pumped into the plasma chamber, gas flow rate, and duration of treatment. For example, hydrogen plasma and oxygen plasma treatments of different durations may be carried out because the oxidation and reduction rates of metal oxide semiconductors in oxygen plasma and hydrogen plasma, respectively, may be different. Alternatively, the durations of hydrogen plasma treatment and/or oxygen plasma treatment may be adjusted according to the gas flow rate and/or gas pressure in the plasma chamber. When the gas flow rate is large and/or when the pressure is high, durations for hydrogen plasma and/or oxygen plasma treatments may be reduced. On the other hand, when the gas flow rate is large and/or when the pressure is low, durations for hydrogen plasma and/or oxygen plasma treatments may be increased.

The conventional chemical doping method for tuning the band gap of metal oxide semiconductors is time-consuming, causes environmental pollution, has a low precision when repeated, is nonreversible, and presents impurities in the metal oxide semiconductors after band gap tuning. In comparison, the method of the invention has the following advantages: (1) convenience; (2) less time-consuming; (3) environmentally friendly, with the sole product being water; (4) repeatability; (5) reversibility; and (6) provides a wider and more flexible range for band gap tuning. Therefore, the method of the invention can overcome the disadvantages of the conventional chemical doping method described previously.

Furthermore, although it is preferred that the invention is used to replace the conventional chemical doping method, however, the method of the invention may also be suitable for doped metal oxide semiconductors such as p-doped ZnO, wherein the dopants may be Li, Na, N, or C, n-doped zinc oxide, wherein the dopants may be B, Al, Ga, or In, Mg- or Be- doped zinc oxide, or Li- or Al-doped copper oxide.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for band gap tuning of metal oxide semiconductors, comprising:
placing a metal oxide semiconductor in a plasma chamber;
(a1) treating the metal oxide semiconductor with an oxygen plasma for oxidizing the metal oxide semiconductor to decrease band gap thereof; and (a2) treating the metal oxide semiconductor with a hydrogen plasma for reducing the metal oxide semiconductor to increase band gap thereof, or
(b1) treating the metal oxide semiconductor with an oxygen plasma for oxidizing the metal oxide semiconductor to increase band gap thereof; and (b2) treating the metal oxide semiconductor with a hydrogen plasma for reducing the metal oxide semiconductor to decrease band gap thereof.

2. The method for band gap tuning of metal oxide semiconductors as claimed in claim 1, wherein the metal oxide semiconductors include zinc oxide (ZnO), tin dioxide (SnO₂), copper oxide (CuO), or combinations thereof.

3. The method for band gap tuning of metal oxide semiconductors as claimed in claim 1, wherein the structures of metal oxide semiconductors include thin-films, nanorods, nanowires, nanocrystals, mesostructures, or combinations thereof.

4. The method for band gap tuning of metal oxide semiconductors as claimed in claim 1, wherein the thickness of the thin film is about 0.5-2 mm.

5. The method for band gap tuning of metal oxide semiconductors as claimed in claim 1, wherein the respective operational power outputs of the oxygen plasma and hydrogen plasma are about 20-50 W.

6. The method for band gap tuning of metal oxide semiconductors as claimed in claim 1, wherein the oxygen plasma treatment is carried out first, and the hydrogen plasma treatment is carried out subsequently.

7. The method for band gap tuning of metal oxide semiconductors as claimed in claim 1, wherein the hydrogen plasma treatment is carried out first, and the oxygen plasma treatment is carried out subsequently.

8. The method for band gap tuning of metal oxide semiconductors as claimed in claim 1, wherein respective operational pressures of the oxygen plasma treatment and the hydrogen plasma treatment are about 100-200 mtorr.

9. The method for band gap tuning of metal oxide semiconductors as claimed in claim 1, wherein oxygen gas and hydrogen gas are introduced into the plasma chamber respectively with flow rates of about 5-10 sccm for forming the oxygen plasma and hydrogen plasma, respectively.

10. The method for band gap tuning of metal oxide semiconductors as claimed in claim 1, wherein respective durations of the oxygen plasma treatment and the hydrogen plasma treatment are about 5-20 minutes.
